(19) United States
(12) Patent Application Publication
(10) Pub. No.: US 2025/0357237 A1
(43) Pub. Date: Nov. 20, 2025

(54) ELECTRONIC STRUCTURE INCLUDING DIE WITH BACKSIDE POWER DELIVERY

(71) Applicant: International Business Machines Corporation, Armonk, NY (US)

(72) Inventors: Mukta Ghate Farooq, Hopewell Junction, NY (US); Arvind Kumar, Stamford, CT (US); Aakrati Jain, Albany, NY (US); Prabudhya Roy Chowdhury, Albany, NY (US)

(21) Appl. No.: 18/663,724

(22) Filed: May 14, 2024

(51) Int. Cl. H01L 23/367; H01L 23/48; H01L 23/528; H01L 25/065

(52) U.S. Cl. CPC H01L 23/367; H01L 23/481; H01L 23/5286; H01L 25/0657; H01L 2225/06589

(57) ABSTRACT

An electronic structure is provided in which the thermal conductance in a semiconductor die including backside back-end-of-the-line (BS-BEOL) structure located on a backside of a front-end-of-the-line (FEOL) level including one or more semiconductor devices, and a frontside back-end-of-the-line (FS-BEOL) structure located on a frontside of the FEOL level is improved by positioning power wires present in the backside BEOL structure in closer proximity to a thermal dissipation structure than signal wires present in the frontside BEOL structure.

### BACKGROUND

The present application relates to semiconductor technology, and more particularly to an electronic structure including a semiconductor die having a backside back-end-of-the-line (BS-BEOL) structure for backside power delivery.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance). Also, placing the power lines on the backside can reduce interference with signal paths and minimize heat buildup near the active device regions.

### SUMMARY

An electronic structure is provided in which the thermal conductance in a semiconductor die including backside back-end-of-the-line (BS-BEOL) structure located on a backside of a front-end-of-the-line (FEOL) level including one or more semiconductor devices, and a frontside back-end-of-the-line (FS-BEOL) structure located on a frontside of the FEOL level is improved by positioning power wires present in the backside BEOL structure in closer proximity to a thermal dissipation structure than signal wires present in the frontside BEOL structure.

In an embodiment of the present application, an electronic structure is provided that includes a semiconductor die including a FEOL level containing at least one semiconductor device, a backside BEOL structure located on a backside of the FEOL level and containing a plurality of first wires having a first cross sectional area and a first thermal resistance, a frontside BEOL structure located on a frontside of the FEOL level and containing a plurality of second wires having a second cross sectional area and a second thermal resistance, and a through via structure extending entirely through the semiconductor die. In the present application, the second cross sectional area is less than the first cross sectional area and the second thermal resistance is greater than the first thermal resistance. The electronic structure further includes a thermal dissipating structure located above the backside BEOL structure, and a packaging substrate located beneath the frontside BEOL structure and electrically connected to the through via structure.

In another embodiment of the present application, an electronic structure is provided that includes a semiconductor die including a FEOL level containing at least one semiconductor device, a backside BEOL structure located on a backside of the FEOL level and containing a plurality of first wires having a first cross sectional area and a first thermal resistance, a frontside BEOL structure located on a frontside of the FEOL level and containing a plurality of second wires having a second cross sectional area and a second thermal resistance, and a through via structure extending entirely through the semiconductor die. In the present application, the second cross sectional area is less than the first cross sectional area and the second thermal resistance is greater than the first thermal resistance. In this embodiment, the electronic structure further includes a carrier wafer located above the backside BEOL structure, a thermal dissipating structure located above the backside BEOL structure, and a packaging substrate located beneath the frontside BEOL structure and electrically connected to the through via structure.

### BRIEF DESCRIPTION OF THE DRAWINGS

FIG. 1 is a cross sectional view of an exemplary electronic structure in accordance with an embodiment of the present application.

FIG. 2 is a cross sectional view of another exemplary electronic structure in accordance with another embodiment of the present application.

FIGS. 3A-3L are cross sectional views illustrating an exemplary processing flow that can be employed in accordance with an embodiment of in the present application.

FIGS. 4A-4L are cross sectional views illustrating another exemplary processing flow that can be employed in accordance with another embodiment of in the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element, or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

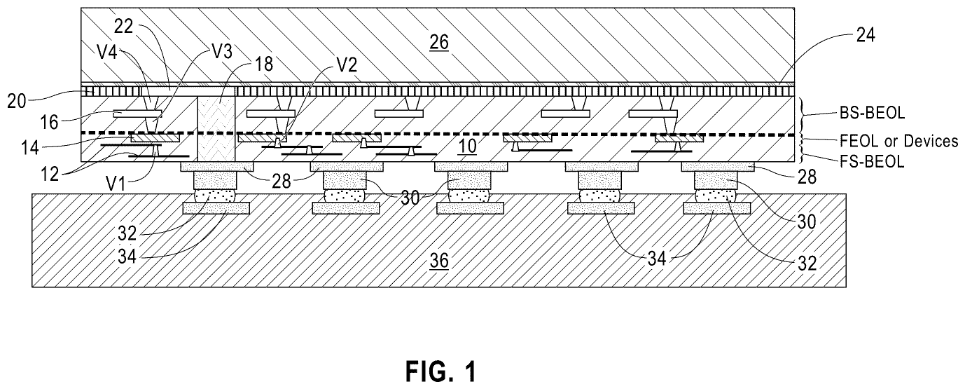

In the present application, an electronic structure is provided in which the thermal conductance in a semiconductor die including a backside BEOL structure located on a backside of a FEOL level, and a frontside BEOL structure located on a frontside of the FEOL level is improved by positioning power wires present in the backside BEOL structure in closer proximity to a thermal dissipation structure than signal wires present in the frontside BEOL structure. Although not specifically described and illustrated, a middle-of-the-line (MOL) level including frontside contact structure embedded in a MOL dielectric material can be positioned between the FEOL level and the frontside BEOL structure. In the present application, the power wires carry power and are referred to as first wires 16 (see, for example, FIG. 1) having a first cross sectional area and a first thermal resistance, while the signal wires carry current and are referred to as second wires 12 (see, for example, FIG. 1) having a second cross sectional area and a second thermal resistance in which the second cross sectional area is less than the first cross sectional area and the second thermal resistance is greater than the first thermal resistance. In the present application, the power wires (e.g., first wires 16) have a greater dimension as compared to the signal wires (e.g., second wires 12). In the semiconductor industry, power wires are oftentimes referred to a fat wires, while signal wires are oftentimes referred to as thin wires.

By positioning the power wires in close proximity to the thermal dissipation structure, the power wires are in the heat flow path and heat can be dissipated through the thermal dissipation structure more easily than is the case when the signal wires are in close proximity to the thermal dissipation structure. The heat generated due to joule heating in the power wires is also easily dissipated through this heat flow path compared to the case when the signal wires are in close proximity to the thermal dissipation structure. These and other aspects of the present application will be described in greater detail herein below.

Referring first to FIG. 1, there is illustrated an exemplary electronic structure in accordance with an embodiment of the present application. The electronic structure illustrated in FIG. 1 includes semiconductor die 10. The semiconductor die 10 includes FEOL level (labeled as “FEOL” in the drawing) containing at least one semiconductor device 14. The at least one semiconductor device 14 can be a transistor, a resistor, a capacitor, or any combination thereof. In one embodiment, the at least one semiconductor device 14 is a transistor. A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. The gate structure includes a gate dielectric and a gate electrode. In the present application, and when a transistor is used as the at least one semiconductor device 14, the transistor can be a planar transistor, or a nano-planar transistor including, but not limited to, a FinFET, a nanosheet transistor, a nanowire transistor, a fork sheet transistor, or a FET stack including at least one transistor stack above another transistor.

In the present application, the FEOL level includes a frontside and a backside. The frontside includes a side of the FEOL level that includes the at least one semiconductor device 14, frontside contact structures (not shown), and a frontside BEOL structure (labeled as “FS-BEOL” in the drawing). The backside of the FEOL level is the side of the FEOL level that is opposite the frontside. The backside includes backside contact structures (not shown), and a backside BEOL structure (labeled as “BS-BEOL” in the drawing).

In some embodiments of the present, the at least one semiconductor device 14 is located on a semiconductor device layer (in the drawings the doted line represents a semiconductor device layer). The semiconductor device layer is positioned between the backside BEOL structure and the at least one semiconductor device 14. The semiconductor device layer can provide structural support for the at least one semiconductor device 14. The semiconductor device layer can also facilitate local heat spreading of heat generated from the at least one semiconductor device layer. The semiconductor device layer is composed of a semiconductor material. The term “semiconductor material” is used throughout the present application to denote a material having semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. When present, the semiconductor device layer is a thin layer whose thickness is about 100 nm to about 1 micron. Although not shown, the semiconductor device layer has at least one through-silicon via structure present therein. The through-silicon via structure provides connectivity between the power wires present in the backside BEOL structure and the at least one semiconductor device 14.

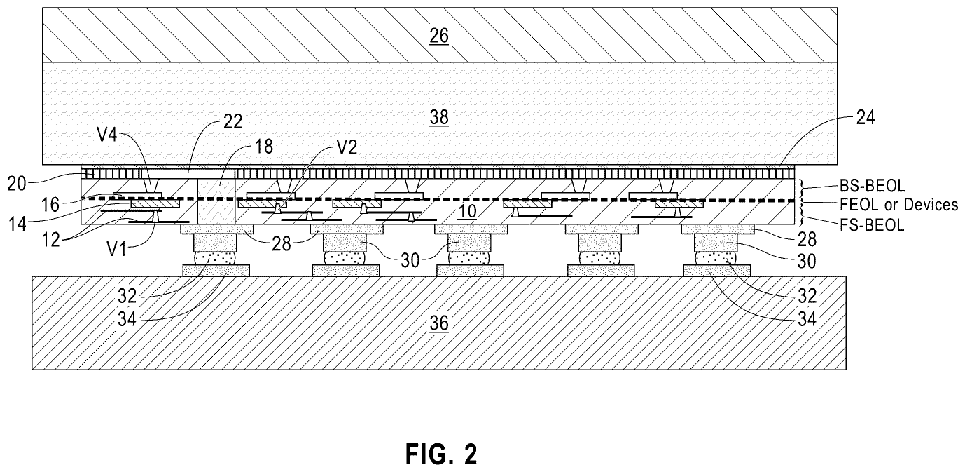

As mentioned above backside BEOL structure is located on a backside of the FEOL level. In FIG. 1 (and FIG. 2) the backside of the FEOL level is located above the BEOL structure. The backside BEOL structure includes a plurality of first wires 16 that are embedded in a backside BEOL structure dielectric material (not specifically shown but included in region labeled as semiconductor die 10) The backside BEOL structure dielectric material is composed of an interlayer dielectric (ILD) material including, but not limited to, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. All dielectric constants mentioned herein are measured in a vacuum unless otherwise stated. In some embodiments, the backside BEOL structure dielectric material is composed of a dielectric material such as, silicon nitride, having a thermal conductivity in the range of 1.2-30 Watts/meter-Kelvin (e.g., W/m-K) or above. Thermal conductivity describes the ability of a material to conduct heat and it provides insights into the ease at which heat can pass through a particular system. Conversely, thermal resistance measures the opposition to heat current in material, and thermal resistance is measured in K/W. Thermal resistance indicates how much temperature difference (in Kelvins) is required to transfer a unit of heat current (in watts) through the material. Thus, materials that have a high thermal conductance have a lower thermal resistance, and materials that have a low thermal conductivity have a high thermal resistance. In the present application, the selection of a backside BEOL structure dielectric material having a “high” thermal conductance can facilitate heat dissipation through the backside BEOL structure easier as compared to embodiments in which a “low” thermal conduction dielectric material is employed as the backside BEOL structure dielectric material.

The first wires 16 (which are illustrated as being at a same backside BEOL structure wiring level) are composed of an electrically conductive metal or an electrically conductive metal alloy. Other first wires 16 can be present in the backside BEOL structure. Illustrative examples of electrically conductive metals that can be used include, but are not limited to, Cu, Al, Co, Ru, Mo, Os, Ir, or Rh. An illustrative electrically conductive alloy that can be used includes, but is not limited to, a Cu—Al alloy. The first wires 16 have a first cross sectional area and a first thermal resistance.

In addition to first wires 16, the backside BEOL structure can also include a plurality of backside BEOL structure via structures. In some embodiments and as is illustrated in FIG. 1, the plurality of backside BEOL structure via structures include lower backside BEOL structure via structures V3 (present at a same level) and upper backside BEOL structure via structures V4 (present at a same level); the upper and lower designation are for the orientation shown in FIGS. 1 and 2. Each backside BEOL structure via structure is composed of an electrically conductive metal or electrically conductive metal alloy, as defined above. Each backside BEOL structure via structure is embedded in a backside BEOL structure dielectric material, as defined above. In some embodiments, and as is illustrated in FIG. 1, a lower backside BEOL structure via structure V3 and an upper backside BEOL structure via structure V4 contact opposing side of one of the first wires 16 of the plurality of first wires. In such an embodiment, the lower backside BEOL structure via structure V3 contacts the at least one semiconductor device 14, and the upper backside BEOL structure via structure V4 is electrically connected to a through via structure 18 that is present in the semiconductor die 10; this connection occurs via a redistribution wire 22 that is present in a redistribution layer that is present on the backside BEOL structure. In some embodiments, the lower backside BEOL structure via structure V3 and the upper backside BEOL structure via structure V4 are stacked to provide a continuous heat flow path.

The semiconductor die 10 also includes frontside BEOL structure located on a frontside of the FEOL level. The frontside BEOL structure includes a plurality of second wires 12 that are embedded in a frontside BEOL dielectric material (not specifically shown but included in region labeled as semiconductor die 10). The frontside BEOL dielectric material is composed of an interlayer dielectric material including those previously mentioned above. In some embodiment of the present application, the plurality of second wires 12 include a first set of second wires 12 that are located at a first BEOL level and a second set of second wires 12 that are located at a second BEOL level that is different from the first BEOL level. Each second wire 12 is composed of an electrically conductive metal or electrically conductive metal alloy as mentioned previously herein. Each second wire 12 has a second cross sectional area and a second thermal resistance.

In addition to second wires 12, the frontside BEOL structure can also include a plurality of frontside BEOL via structures. In some embodiments and as is illustrated in FIG. 1, the plurality of frontside BEOL via structures includes lower frontside BEOL via structures V1 (present at a same level) and upper frontside BEOL via structure V2 (present at a same level). Each frontside BEOL via structure is composed of an electrically conductive metal or electrically conductive metal alloy, as defined above. Each frontside BEOL via structure is embedded in frontside BEOL dielectric material, as also defined above. In some embodiments, and as is illustrated in FIG. 1, a lower frontside BEOL via structure V1 is used to electrically connect a second wire 12 present at a first level to a second wire 12 that is present at a second level that is different from the first level, and an upper frontside BEOL via structure V2 is used to electrically connect the second wire 12 that is present at the second level to the at least one semiconductor device 14.

As mentioned above, the semiconductor die 10 also includes a through via structure 18. The through via structure 18 extends entirely through the semiconductor die 10. That is, the through via structure 18 extends entirely through each of the backside BEOL structure, the FEOL level and the frontside BEOL structure. The through via structure 18 has a first surface that is substantially coplanar with a topmost surface of the semiconductor die 10 and a second surface opposite the first surface that is substantially coplanar with a bottom surface of the semiconductor die 10. The through via structure 18 is composed of an electrically conductive metal or an electrically conductive metal as defined above. Although not shown, a diffusion barrier liner can be present along the sidewall of the through via structure 18. In the present application, power from an external source that is connected to packaging substate 36 travels through the via solder ball 32 and into the through via structure 18 which in turn delivers the power to the backside BEOL structure.

As is also shown in FIG. 1, the electronic structure further includes a thermal dissipating structure 26 located above the backside BEOL structure. The thermal dissipating structure 26 includes any structure or material that can dissipate heat away from the semiconductor die 10. In some embodiments, the thermal dissipation structure 26 can be a thermal interface material, a lid (typically composed of a conductive material), a heat sink or any combination thereof.

In some embodiments (not shown), a carrier wafer as shown in FIG. 2 can be attached to the thermal dissipation structure 26 and positioned between the thermal dissipation structure 16 and the semiconductor die 10. When present, the carrier wafer is composed of one of the semiconductor materials mentioned above. For example, the carrier wafer can be a Si carrier wafer.

In embodiments of the present application and as shown in FIG. 1, a redistribution layer is positioned between the backside BEOL structure and the thermal dissipation structure 26. The redistribution layer (or “RDL” for short) includes a redistribution wire 22 that has a first portion that contacts the through via structure 18 and a second portion that is electrically connected to the at least one semiconductor device 14 through one of the first wires 16 present in the backside BEOL structure. The redistribution wire 22 is composed of an electrically conductive metal or an electrically conductive metal alloy as mentioned above. The redistribution wire 22 has a third cross sectional area that can be equal to or greater than the first cross sectional area of the first wires 16 present in the backside BEOL structure. The redistribution wire 22 is embedded in a redistribution dielectric material 20. The redistribution dielectric material 20 can include any dielectric material including the ILD materials previously mentioned herein. The redistribution dielectric material can also include such as, for example, polyimide, polybenzoxazole or benzocyclobutene, In some embodiments, the redistribution dielectric material 20 is composed of a dielectric material such as, silicon nitride, having a thermal conductivity in the range of 1.2-30 W/m-K or above.

In some embodiments and as is illustrated in FIG. 1, the redistribution layer is spaced apart from the thermal dissipating structure 26 by a dielectric layer 24; dielectric layer 24 can be present between the carrier wafer and the redistribution layer when a carrier wafer is present. In some embodiments, the dielectric layer 24 can be composed of a bonding dielectric material such as, for example, TEOS (tetraethyl ortho silicate), SiO₂, SiCN, and/or SiCOH. In other embodiments, the dielectric layer 24 is composed of a dielectric material such as, for example, silicon nitride or silicon oxynitride, other than a bonding dielectric material. In some embodiment, dielectric layer 24 can be omitted from the electronic structure of FIG. 1.

The electronic structure illustrated in FIG. 1 also includes packaging substrate 36 located beneath the frontside BEOL structure and electrically connected to the through via structure 18. The packaging substrate 36 includes materials that are well known in semiconductor device manufacturing. The packaging substrate 36 can include, for example, a laminate, a printed circuit board, an organic interposer, a silicon interposer or a glass interposer.

As illustrated in FIG. 1, the frontside BEOL structure of the semiconductor die 10 is attached to the packaging substrate 36 by a plurality of solder balls 32; throughout the present application solder balls also include solder bumps. In accordance with the present application, at least one of the solder balls of the plurality of solder balls 32 is in contact with the through via structure 18. Solder balls 32 include any well-known solder ball material. In embodiments, semiconductor die bond pads 28 are present on the frontside BEOL structure of the semiconductor die 10 and packaging bond pads 34 are present on the packaging substrate 36. The semiconductor die bond pads 28 and the packaging bond pads 34 are both composed an electrically conductive metal or electrically conductive metal as previously mentioned herein. Typically, Cu is used as the bond pad material for both the semiconductor die bond pads 28 and the packaging bond pads 34. In some embodiments and as is illustrated in FIG. 1, an under bump metallurgical structure 30 is positioned between the solder ball 32 and the semiconductor die bond pads 28. When present, the under bump metallurgical (UBM) structure 30 is composed of a UBM material such as, for example, Cu, Ni, Au or Ag.

Referring now to FIG. 2, there is illustrated another exemplary electronic structure in accordance with another embodiment of the present application. The electronic structure of FIG. 2 is similar to the electrically structure illustrated in FIG. 1 in that both include semiconductor die 10 including a FEOL level containing at least one semiconductor device 14 (both as device above), a backside BEOL structure (as defined above, but minus the level including the lower backside BEOL structure via structures V3) located on a backside of the FEOL level and containing a plurality of first wires 16 (as defined above) having a first cross sectional area and a first thermal resistance (as defined above), a frontside BEOL structure (as defined above) located on a frontside of the FEOL level and containing a plurality of second wires 12 (as defined above) having a second cross sectional area and a second thermal resistance (as defined above), and a through via structure 18 (as defined above) extending entirely through the semiconductor die 10. In the present application, the second cross sectional area is less than the first cross sectional area and the second thermal resistance is greater than the first thermal resistance. In this embodiment, the electronic structure further includes carrier wafer 38 (as defined above) located above the backside BEOL structure, a thermal dissipating structure 26 (as defined above) located above the backside BEOL structure, and a packaging substrate 36 (as defined above) located beneath the frontside BEOL structure and electrically connected to the through via structure 18. Carrier Wafer 38 is used for structural support.

The exemplary electronic structure illustrated in FIG. 2 also includes the redistribution layer including the redistribution dielectric material 20 and redistribution wire 22 (as both defined above), and dielectric layer 24 as defined above. Dielectric layer 24 is an optional layer. In some embodiment, the carrier wafer 38 can be omitted from the exemplary electronic device illustrated in FIG. 2. An optional semiconductor device layer, as defined above, can also be present in the exemplary electronic device illustrated in FIG. 2. The exemplary electronic structure illustrated in FIG. 2 solder balls 32, semiconductor die bond pads 28, packaging bond pads 34, and UBM structure 30, all of which are as defined above.

In this embodiment of the present application, the through via structure 18 has a height that is shorter than a height of the through via structure 18 illustrated in FIG. 1. The shorter through via structure 18 height is because the backside BEOL structure of the electronic structure illustrated in FIG. 2 lacks the level including the lower backside BEOL structure via structures V3. Notably, and in the exemplary electronic structure illustrated in FIG. 2, the backside BEOL structure includes one upper backside BEOL structure via structure V4 contacting one of the first wires 16 of the plurality of first wires. The upper backside BEOL structure via structure V4 is electrically connected to the through via structure 18, and the first wiring 16 that contacts the upper backside BEOL structure via structure V4 is in direct physical contact with the at least one semiconductor device 14.

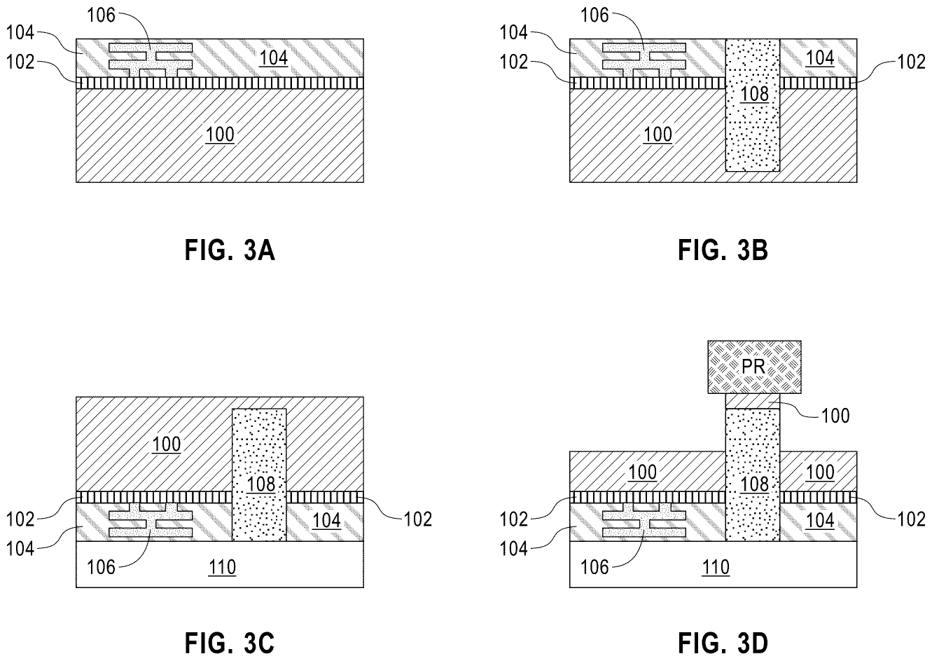

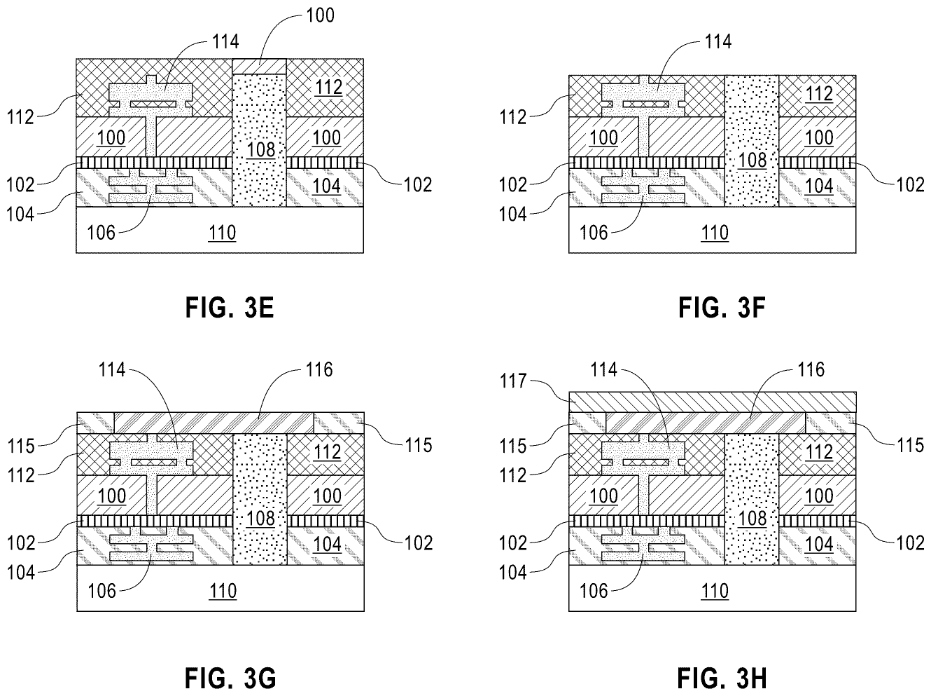

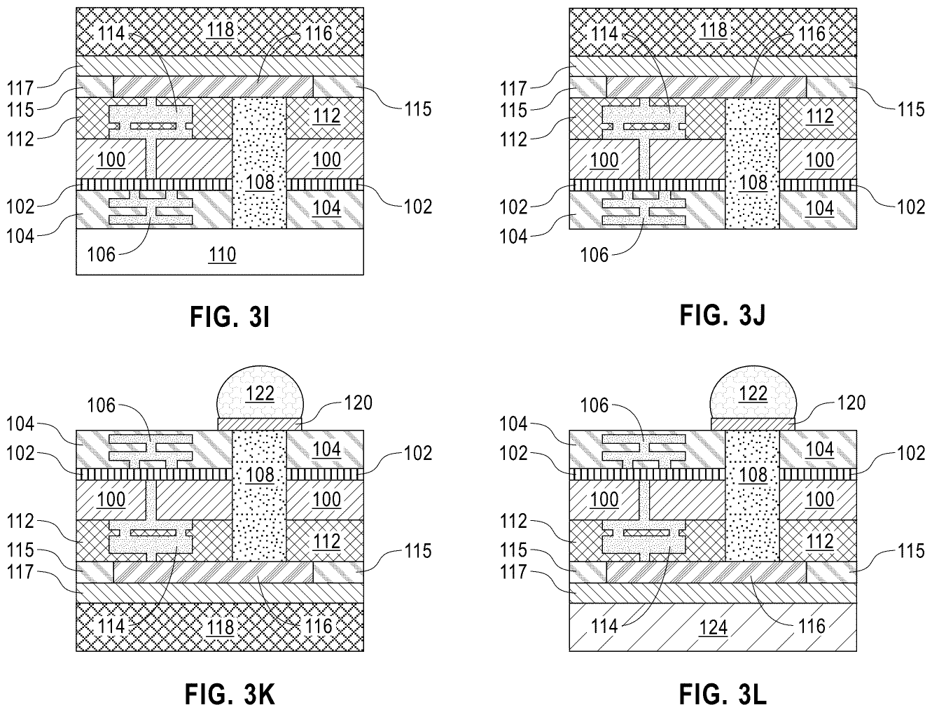

Reference is now made to FIGS. 3A-3L, which illustrate an exemplary processing flow that can be employed in accordance with an embodiment of in the present application. This processing flow can be used to provide the exemplary electronic structure shown in FIGS. 1 and 2. Referring first to FIG. 3A, there is illustrated an exemplary structure that includes semiconductor device layer 100, a FEOL level 102 including at least one semiconductor device (not specifically shown but meant to be included within the FEOL level 102; note that the at least one semiconductor device within the FEOL level 102 is the same as the semiconductor device 14 illustrated in FIGS. 1 and 2) as mentioned above, and a frontside BEOL structure that includes BEOL wiring 106 embedded in frontside BEOL dielectric region 104. The semiconductor device layer 100 includes a semiconductor material as mentioned above. The FEOL level 102 including the at least one semiconductor device can be formed utilizing materials and FEOL processes that are well known in the art. The frontside BEOL structure illustrated in FIG. 3A can be formed utilizing any well known BEOL process. The frontside BEOL dielectric region 104 includes one or more frontside BEOL dielectric materials, as defined above. The BEOL wiring 106 is composed of an electrically conductive metal or an electrically conductive metal alloy as mentioned above. The BEOL wiring 106 illustrated in FIG. 3A is equivalent to the second wires 12, the lower and upper frontside BEOL via structures V1 and V2 illustrated in FIGS. 1 and 2. The BEOL wiring 106 can be formed utilizing techniques that are well known to those skilled in the art. For example, a damascene and/or a subtractive etching process can be used to form the BEOL wiring 106. The frontside BEOL dielectric region 104 can be formed by one or more deposition processes in which a planarization process such as, for example, chemical mechanical planarization (CMP) can follow each of the deposition processes.

Next, and as is shown in FIG. 3B, a through via structure 108 (note that the through via structure 108 of FIG. 2B is equivalent to the through via structure 18 illustrated in FIGS. 1 and 2) is formed. The through via structure 108 is composed of an electrically conductive metal or an electrically conductive metal alloy as mentioned above. The through via structure 108 can be formed by a metallization process which includes forming an opening into a structure/material, filling the opening with a desired material, and then performing a planarization. As is shown, the through via structure 108 is formed entirely through the frontside BEOL structure and the FEOL level 102 and at least partially through the semiconductor device layer 100.

FIG. 3C illustrates the exemplary structure after attaching the frontside BEOL structure to a handler wafer 110 and thereafter flipping the exemplary structure 180° such that the semiconductor device layer 100 is physically exposed. The handler wafer 110 is typically composed of a semiconductor material as defined above. The attaching of the handler wafer 110 to the frontside BEOL structure includes a bonding process. Flipping, which will allow backside processing of the exemplary structure, can be performed by hand or by a mechanical device such as, for example, a robot arm.

Next, and as is shown in FIG. 3D, a patterned photoresist (PR) is formed (by deposition and lithography) to protect the though via structure 108, and then at least a portion (or an entirety of) the semiconductor device layer 100 is removed utilizing a material removal process that is selective in removing the semiconductor device layer 100. In FIG. 3D and by way of one example, a thin portion (about 100 nm or less) remains after the material removal process. The patterned photoresist is removed utilizing a material removal process that is selective in removing the patterned photoresist from the exemplary structure.

After removing the photoresist, and as is shown in FIG. 3E, a backside BEOL structure is formed. The backside BEOL structure includes BS-BEOL wiring 114 embedded in a BS-BEOL dielectric region 112. Note that the BS-BEOL dielectric region 112 also embeds a portion of the through via structure 108 as well as a portion of the semiconductor device layer 100 that is located on the through via structure 108. The BS-BEOL dielectric region 112 includes one or more backside BEOL structure dielectric material as defined above. The BS-BEOL wiring 114 is composed of an electrically conductive metal or an electrically conductive metal alloy as mentioned above. The BS-BEOL wiring 114 illustrated in FIG. 3E is equivalent to the first wires 16, the backside power distribution via structures V3 and V4 illustrated in FIG. 1 (as well as FIG. 2 minus V3). The BS-BEOL wiring 114 can be formed utilizing techniques that are well known to those skilled in the art. For example, a damascene and/or a subtractive etching process can be used to form the BS-BEOL wiring 114. The BS-BEOL dielectric region 112 can be formed by one or more deposition processes in which a planarization process such as, for example chemical mechanical planarization can follow each of the deposition processes.

Next, and as illustrated in FIG. 3F, there is shown the exemplary structure of FIG. 3E after performing a planarization to reveal the through via structure 198. The planarization process removes an upper portion of the BS-BEOL dielectric region 112 and the semiconductor device layer 100 that was present on the through via structure 108. The through via structure 108 now extends completely through the backside BEOL structure, the semiconductor device layer 100 (if the same is present), the FEL level 102, and the frontside BEOL structure.

FIG. 3G illustrates the exemplary structure after forming a redistribution layer that includes a redistribution wire 116 (which is equivalent to the redistribution wire 22 illustrated in FIGS. 1 and 2) embedded in a redistribution dielectric material 115 (which is equivalent to the redistribution dielectric material 20 illustrated in FIGS. 1 and 2). The redistribution wire 116 is composed of an electrically conductive metal or electrically conductive metal alloy as mentioned above. The redistribution dielectric material 115 includes a dielectric material including dielectric materials and polymeric materials previously mentioned herein for the redistribution dielectric material 20. The redistribution layer can be formed by a damascene or a subtractive etching process.

After forming the redistribution layer and as is shown in FIG. 3H, a dielectric layer 117 (equivalent to dielectric layer 24 shown in FIGS. 1 and 2) is formed by a deposition process. The dielectric layer 117 can include a non-bonding dielectric material or a bonding dielectric material as mentioned above for dielectric layer 24. Next, and as is illustrated in FIG. 3I, another handler wafer 118 is formed utilizing a bonding process. The handler wafer 118 can be composed of a semiconductor material as defined above. FIG. 3J illustrates the exemplary structure of FIG. 3I after removing handler wafer 110 to physically exposed the frontside BEOL structure. The removal of hander wafer 110 includes a material removal process that is selective in removing the handler wafer 110.

Referring now to FIG. 3K, there is illustrated the exemplary structure of FIG. 3I after flipping the structure 180° C. and forming bond pads 120 (equivalent to semiconductor die bond pads 28 illustrated in FIGS. 1 and 2) and solder balls 122 (equivalent to solder balls solder balls 32 illustrated in FIGS. 1 and 2). The bond pads 120 can be formed by deposition and etching an electrically conductive metal or an electrically conductive metal alloy as mentioned above. Solder balls 122 include well known solder material and can be formed utilizing techniques well known in the art.

Referring now to FIG. 3L, there is illustrated the exemplary structure of FIG. 3K after removing the handler wafer 118 by a material removal process) and forming a carrier wafer 124. Carrier wafer 124 can include a semiconductor material as defined herein. A dicing process can then be performed and thereafter the diced portions of the exemplary structure can be bonded to a packaging substrate (not shown) through solder balls 122. In some embodiments, the carrier wafer 124 can be removed after attaching to the packaging substrate and a heat dissipation structure (not shown) can be formed on dielectric layer 117 (or on the carrier wafer 124). These processing steps illustrated in FIGS. 3A-3L providing the exemplary electronic structure shown in FIGS. 1 and 2.

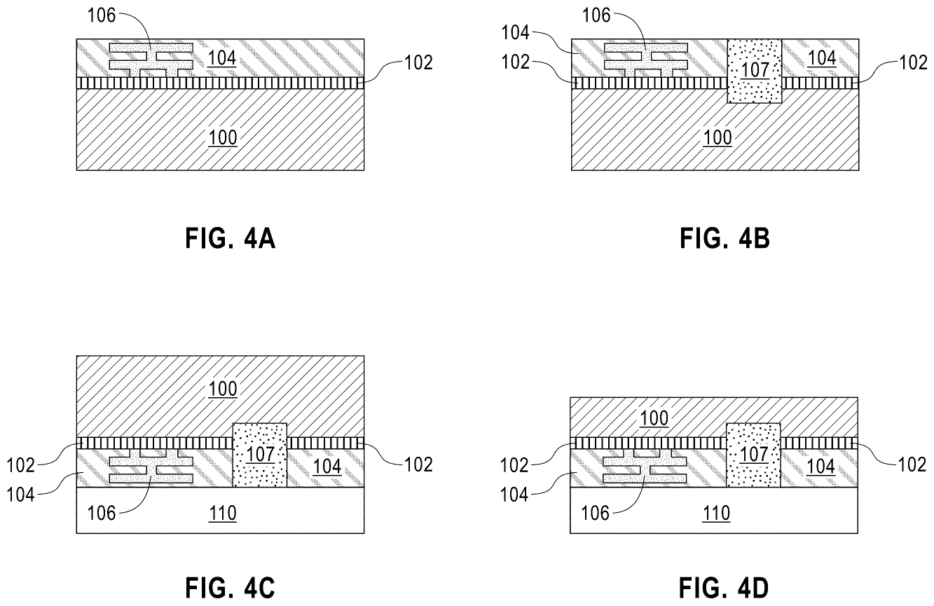

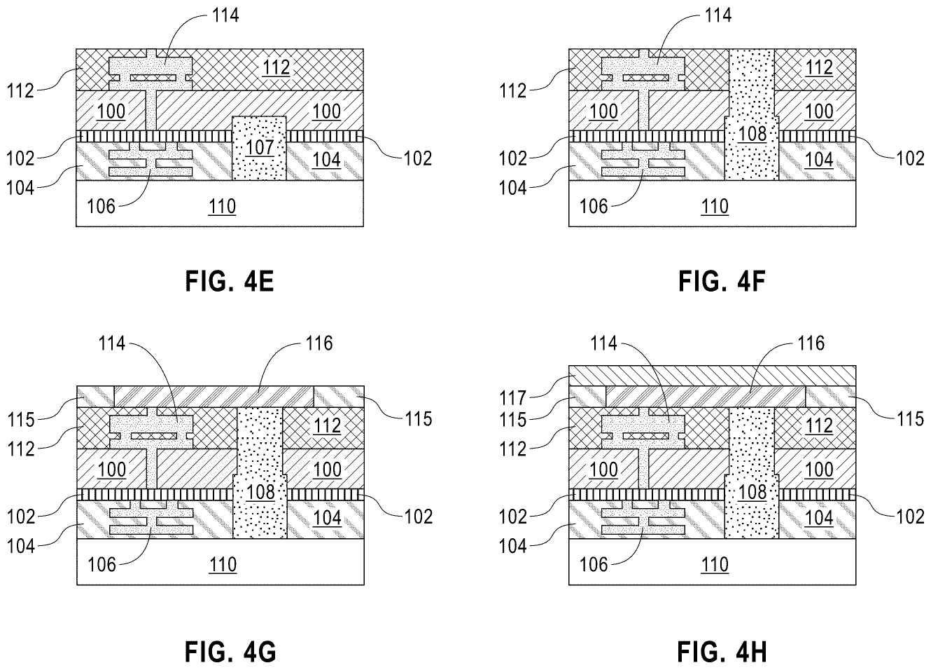

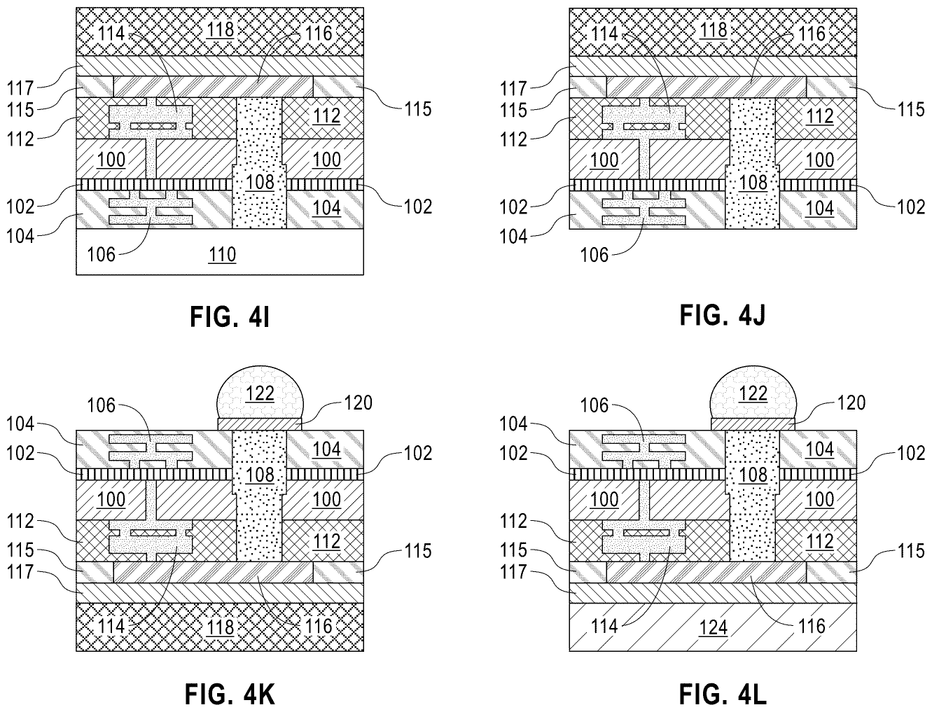

Reference is now made to FIGS. 4A-4L, which illustrate another exemplary processing flow that can be employed in accordance with another embodiment of the present application. The exemplary processing flow illustrated in FIGS. 4A-4L can be used in providing the exemplary electronic structure shown in FIGS. 1 and 2. This process flow begins as shown in FIG. 4A by providing semiconductor device layer 100, FEOL level 102 including one semiconductor device (not shown, but equivalent to semiconductor device 16 shown in FIGS. 1 and 2), and frontside BEOL structure including BEOL wiring 106 embedded in frontside BEOL dielectric region 104. Each of the elements shown in FIG. 4A are the same as that shown in FIG. 3A above, thus the materials and technique used in providing the exemplary structure shown in FIG. 3A apply here for the exemplary structure shown in FIG. 4A.

Referring now to FIG. 4B, there is illustrated the exemplary structure of FIG. 4A after forming a precursor through via structure 107. The precursor through via structure 107 is composed of an electrically conductive metal or an electrically conductive metal alloy as mentioned above. The precursor through via structure 107 can be formed by a metallization process as defined above. As is shown, the precursor through via structure 107 is formed entirely through the frontside BEOL structure and the FEOL level 102 and partially through the semiconductor device layer 100.

Referring now to FIG. 4C, there is illustrated the exemplary structure of FIG. 4D after attaching the frontside BEOL structure to handler wafer 110 and thereafter flipping the exemplary structure 180° such that the semiconductor device layer 100 is physically exposed.

Referring now to FIG. 4D, there is illustrated the exemplary structure of FIG. 4C after thinning the semiconductor device layer 100. The thinning step can include an etching process that is selective in removing the semiconductor device layer 100. Typically, the semiconductor device layer 100 is thinned to a thickness of about 100 nm or less.

Referring now to FIG. 4E, there is illustrated the exemplary structure of FIG. 4D after forming a backside power distribution. The backside BEOL structure includes BS-BEOL wiring 114 embedded in a BS-BEOL dielectric region 112, both of which have been defined above with respect to the exemplary structure shown in FIG. 3E.

Referring now to FIG. 4F, there is illustrated the exemplary structure of FIG. 4E after forming another through via structure that connects to the precursor through via structure 107. Collectively, the precursor through via structure 107 and the another through via structure form through via structure 108 illustrated in FIG. 4F. The another through via structure includes an electrically conductive metal or electrically conductive metal alloy as described herein, and the another through via structure can be formed by a damascene process. The another through via structure can have a same width, or a different width that the precursor through via structure 107. As is shown in FIG. 4F, through via structure 108 extends entirely through the frontside BEOL structure, the semiconductor device layer 100, and the backside BEOL structure.

Referring now to FIG. 4G, there is illustrated the exemplary structure of FIG. 4F after forming a redistribution layer that includes a redistribution wire 116 (which is equivalent to the redistribution wire 22 illustrated in FIGS. 1 and 2) embedded in a redistribution dielectric material 115 (which the redistribution dielectric material 20 illustrated in FIGS. 1 and 2). The redistribution layer used in this embodiment is the same as that described with respect to the exemplary structure shown in FIG. 3G.

Referring now to FIG. 4H, there is illustrated the exemplary structure of FIG. 4G after forming dielectric layer 117 (equivalent to dielectric layer 24 shown in FIGS. 1 and 2). The dielectric layer 117 used in this embodiment is the same as that described with respect to the exemplary structure shown in FIG. 3H.

Referring now to FIG. 4I, there is illustrated the exemplary structure of FIG. 4H after forming another handler wafer 118. The handler wafer 118 used in this embodiment is the same as that described with respect to the exemplary structure shown in FIG. 3I.

Referring now to FIG. 4J, there is illustrated the exemplary structure of FIG. 4I after removing handler wafer 110 to physically exposed the frontside BEOL structure. The removal of hander wafer 110 includes a material removal process that is selective in removing the handler wafer 110.

Referring now to FIG. 4K, there is illustrated the exemplary structure of FIG. 4J after flipping the structure 180° C. and forming bond pads 120 (equivalent to semiconductor die bond pads 28 illustrated in FIGS. 1 and 2) and solder balls 122 (equivalent to solder balls solder balls 32 illustrated in FIGS. 1 and 2). The bond pads 120 and solder balls 122 used in this embodiment is the same as that described with respect to the exemplary structure shown in FIG. 3K.

Referring now to FIG. 4L, there is illustrated the exemplary structure of FIG. 4K after removing the handler wafer 118 by a material removal process) and forming a carrier wafer 124. Carrier wafer 124 can include a semiconductor material as defined herein. A dicing process can then be performed and thereafter the diced portions of the exemplary structure can be bonded to a packaging substrate (not shown) through solder balls 122. In some embodiments, the carrier wafer 124 can be removed after attaching to the packaging substrate and a heat dissipation structure (not shown) can be formed on dielectric layer 117 (or on the carrier wafer 124). These processing steps illustrated in FIGS. 4A-4L providing the exemplary electronic structure shown in FIGS. 1 and 2.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An electronic structure comprising:
a semiconductor die comprising a front-end-of-the-line (FEOL) level comprising at least one semiconductor device, a backside back-end-of-the-line (BEOL) structure located on a backside of the FEOL level and comprising a plurality of first wires having a first cross sectional area and a first thermal resistance, a frontside BEOL structure located on a frontside of the FEOL level and comprising a plurality of second wires having a second cross sectional area and a second thermal resistance, wherein the second cross sectional area is less than the first cross sectional area and the second thermal resistance is greater than the first thermal resistance, and a through via structure extending entirely through the semiconductor die;
a thermal dissipating structure located above the backside BEOL structure; and
a packaging substrate located beneath the frontside BEOL structure and electrically connected to the through via structure.

2. The electronic structure of claim 1, wherein the thermal dissipating structure comprises a thermal interface material, a lid, a heat sink or any combination thereof.

3. The electronic structure of claim 1, further comprising a redistribution layer positioned between the thermal dissipating structure and the backside BEOL structure, wherein the redistribution layer comprises a redistribution wire the contacts the through via structure and is electrically connected to the at least one semiconductor device through one of the first wires present in the backside BEOL structure.

4. The electronic structure of claim 3, wherein the redistribution wire is embedded in a redistribution dielectric material having a thermal conductivity in the range of 1.2-30 W/m-K or above.

5. The electronic structure of claim 3, wherein the redistribution layer is spaced apart from the thermal dissipating structure by a dielectric layer.

6. The electronic structure of claim 1, wherein the FEOL level further comprises a semiconductor device layer located beneath the at least one semiconductor device.

7. The electronic structure of claim 1, wherein the plurality of first wires of the backside BEOL structure are embedded in a backside BEOL structure dielectric material having a thermal conductivity in the range of 1.2-30 W/m-K or above.

8. The electronic structure of claim 1, further comprising a lower backside BEOL structure via structure and an upper backside BEOL structure via structure contacting opposing side of one of the first wires of the plurality of first wires, wherein the lower backside BEOL structure via structure contacts the at least one semiconductor device, and the upper backside BEOL structure via structure is electrically connected to the through via structure.

9. The electronic structure of claim 1, wherein the lower backside BEOL structure via structure and the upper backside BEOL structure via structure are stacked to provide a continuous heat flow path.

10. The electronic structure of claim 1, wherein the frontside BEOL structure is attached to the packaging substrate by a plurality of solder balls, wherein at least one of the solder balls of the plurality of solder balls is in contact with the through via structure.

11. An electronic structure comprising:
a semiconductor die comprising a front-end-of-the-line (FEOL) level comprising at least one semiconductor device, a backside back-end-of-the-line (BEOL) structure located on a backside of the FEOL level and comprising a plurality of first wires having a first cross sectional area and a first thermal resistance, a frontside BEOL structure located on a frontside of the FEOL level and comprising a plurality of second wires having a second cross sectional area and a second thermal resistance, wherein the second cross sectional area is less than the first cross sectional area and the second thermal resistance is greater than the first thermal resistance, and a through via structure extending entirely through the semiconductor die;
a carrier wafer located above the backside BEOL structure;
a thermal dissipating structure located above the backside BEOL structure; and
a packaging substrate located beneath the frontside BEOL structure and electrically connected to the through via structure.

12. The electronic structure of claim 11, wherein the thermal dissipating structure comprises a thermal interface material, a lid, a heat sink or any combination thereof.

13. The electronic structure of claim 11, further comprising a redistribution layer positioned between the carrier wafer and the backside BEOL structure, wherein the redistribution layer comprises a redistribution wire the contacts the through via structure and is electrically connected to the at least one semiconductor device through one of the first wires present in the backside BEOL structure.

14. The electronic structure of claim 13, wherein the redistribution wire is embedded in a redistribution dielectric material having a thermal conductivity in the range of 1.2-30 W/m-K or above.

15. The electronic structure of claim 13, wherein the redistribution layer is spaced apart from the carrier wafer by a dielectric layer.

16. The electronic structure of claim 11, wherein the FEOL level further comprises a semiconductor device layer located beneath the at least one semiconductor device.

17. The electronic structure of claim 11, wherein the plurality of first wires of the backside BEOL structure are embedded in a backside BEOL structure dielectric material having a thermal conductivity in the range of 1.2-30 W/m-K or above.

18. The electronic structure of claim 11, further comprising an upper backside BEOL structure via structure contacting one of the first wires of the plurality of first wires, wherein the upper backside BEOL structure via structure is electrically connected to the through via structure, and wherein the first wiring that contacts the upper backside BEOL structure via structure is in direct physical contact with the at least one semiconductor device.

19. The electronic structure of claim 11, wherein the frontside BEOL structure is attached to the packaging substrate by a plurality of solder balls, wherein at least one of the solder balls of the plurality of solder balls is in contact with the through via structure.
